(19) United States
(12) Patent Application Publication
(10) Pub. No.: US 2024/0389419 A1
(43) Pub. Date: Nov. 21, 2024

(54) SPLICED DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Na LIU, Wuhan (CN); Chunpeng ZHANG, Wuhan (CN); Wenxu XIANYU, Wuhan (CN)

(21) Appl. No.: 17/615,341

(22) PCT Filed: Nov. 12, 2021
(86) PCT No.: PCT/CN2021/130280

§ 371 Date: Aug. 8, 2024

(30) Foreign Application Priority Data
Nov. 2, 2021 (CN) 202111288403.7

(51) Int. Cl. H10K 59/19

(52) U.S. Cl. CPC H10K 59/19

(57) ABSTRACT

A device and a spliced display panel are provided. The spliced display panel includes a display component in a display area, each display component comprises a first connection terminal and a display substrate electrically connected to the first connection terminal. A driving backplane comprises a connecting circuit layer in the display area. The connecting circuit layer comprises a second connection terminal bound to the first connection terminal. The display component is arranged in an array on the driving backplane. A driving integrated circuit electrically is connected to the second connection terminal.

### FIELD OF INVENTION

The present application relates to a field of display technology, and more particularly, to a spliced panel and a display device.

### DESCRIPTION OF PRIOR ART

With the development of display technology, flexible organic light emitting diode (OLED) technology with high resolution and high refresh rate has gradually become the mainstream display technology. Currently, OLED technology has been widely used in mobile phones, tablets, notebook computers, and other fields. However, due to the low temperature poly-silicon (LTPS) device characteristics of flexible OLEDs, the maximum size of the OLEDs is less than 20 inches, which is not suitable for large-size household appliances, electronic products, automobiles, medical fields, etc.

Currently, large-size OLED displays are mainly realized by splicing technology. Nowadays there are problems such as large frames, difficulty in technical realization, and complicated processes.

### SUMMARY OF INVENTION

### Technical Problem

Therefore, conventional large-size spliced display screens have relatively large frames and complicated processes that need to be resolved.

### Solutions for Technical Problem

### Technical Solutions

A spliced display panel comprises a display area and a non-display area on a side of the display area. The spliced display panel further comprises: a plurality of display components in the display area, and each of the display components comprises a plurality of first connection terminals and a display substrate electrically connected to the first connection terminals; a driving backplane comprising a connecting circuit layer in the display area, and the connecting circuit layer comprises a plurality of second connection terminals bound to the plurality of first connection terminals, and a plurality of the display components are arranged in an array on the driving backplane; and a driving integrated circuit electrically connected to the plurality of second connection terminals. The driving integrated circuit sequentially transmits signals to the plurality of first connection terminals and the display substrate through the plurality of second connection terminals to drive the display substrate to emit light.

In one embodiment, the driving backplane further comprises a substrate layer, and the connecting circuit layer and the driving integrated circuit are disposed on the substrate layer.

In one embodiment, the connecting circuit layer further comprises a connection trace, a first interlayer insulating layer, and a second interlayer insulating layer in the display area, the first interlayer insulating layer is disposed on the substrate layer, the connection trace is disposed on the first interlayer insulating layer, the second interlayer insulating layer is disposed on the connection trace, the second connection terminal is electrically connected to the connection trace and the first connection terminal through a first via hole penetrating the second interlayer insulating layer, the driving integrated circuit in the non-display area is electrically connected to the connection trace, and orthographic projections of the driving integrated circuit and the connection trace projected on the substrate layer do not overlap each other.

In one embodiment, the display substrate comprises: a substrate; a driving circuit layer disposed on a side of the substrate away from the driving backplane; the driving circuit layer is electrically connected to the first connection terminal; and a light-emitting function layer, wherein the first connection terminal is disposed on a surface of the substrate facing the driving backplane and is electrically connected to the light-emitting function layer.

In one embodiment, the connecting circuit layer further comprises a driving function layer in the display area, the second connection terminal is electrically connected to the driving function layer through a first via hole of the connecting circuit layer, the driving integrated circuit is disposed in the non-display area and electrically contacts the driving function layer, and orthographic projections of the driving integrated circuit and the driving function layer projected on the substrate layer do not overlap each other.

In one embodiment, the connecting circuit layer further comprises a first interlayer insulating layer and a second interlayer insulating layer on the substrate layer. The driving function layer comprises: a second buffer layer disposed on the first interlayer insulating layer; a second semiconductor layer disposed on the second buffer layer; a sixth interlayer insulating layer disposed on the second buffer layer and covering the second semiconductor layer; a third gate disposed on the sixth interlayer insulating layer and being opposite the second semiconductor layer; a seventh interlayer insulating layer disposed on the sixth interlayer insulating layer and covering the third gate, and the second interlayer insulating layer is disposed on the seventh interlayer insulating layer; a fourth gate disposed on the seventh interlayer insulating layer, and the second interlayer insulating layer covers the fourth gate, and the first via hole is electrically connected to the second semiconductor layer; and a third connection terminal and a fourth connection terminal disposed on the second interlayer insulating layer, and the third connection terminal is electrically connected to the fourth connection terminal, the third connection terminal is electrically connected to the second semiconductor layer through a fifth via hole of the connecting circuit layer, and the driving integrated circuit electrically contacts the fourth connection terminal.

In one embodiment, the connecting circuit layer further comprises a driving function layer in the display area, the second connection terminal is electrically connected to the driving function layer through the first via hole, the driving integrated circuit is disposed on the substrate layer in the display area, and the connecting circuit layer is disposed on the drive integrated circuit, the connecting circuit layer is further provided with a sixth via hole, and the driving integrated circuit is electrically connected to the driving function layer through the sixth via hole.

In one embodiment, the connecting circuit layer further includes a first interlayer insulating layer and a second interlayer insulating layer on the substrate layer; and the driving function layer comprises: a second buffer layer disposed on the first interlayer insulating layer; a second semiconductor layer disposed on the second buffer layer; a sixth interlayer insulating layer disposed on the second buffer layer and covering the second semiconductor layer; a third gate disposed on the sixth interlayer insulating layer and being opposite the second semiconductor layer; a seventh interlayer insulating layer disposed on the sixth interlayer insulating layer and covering the third gate, and the second interlayer insulating layer is disposed on the seventh interlayer insulating layer; a fourth gate disposed on the seventh interlayer insulating layer, and the second interlayer insulating layer covers the fourth gate, and the first via hole is electrically connected to the second semiconductor layer; and a third connection terminal disposed on the second interlayer insulating layer, and the third connection terminal is electrically connected to the second semiconductor layer through a fifth via hole of the connecting circuit layer and is electrically connected to the driving integrated circuit through the sixth via hole.

In one embodiment, the connecting circuit layer further comprises a sealing layer, and the sealing layer is disposed between the display component and the driving backplane and covers the first connection terminal and the second connection terminal.

In one embodiment, the connecting circuit layer further comprises a sealing layer, and the sealing layer is disposed between the display component and the driving backplane and covers the first connection terminal and the second connection terminal.

A display device comprises: a housing defining a containing cavity and a spliced display panel. The spliced display panel is disposed in the containing cavity. The spliced display panel comprises a display area and a non-display area on a side of the display area. The spliced display panel further comprises: a plurality of display components in the display area, and each of the display components comprises a plurality of first connection terminals and a display substrate electrically connected to the first connection terminals; a driving backplane comprising a connecting circuit layer in the display area, and the connecting circuit layer comprises a plurality of second connection terminals bound to the plurality of first connection terminals, and a plurality of the display components are arranged in an array on the driving backplane; and a driving integrated circuit electrically connected to the plurality of second connection terminals, and the driving integrated circuit sequentially transmits signals to the plurality of first connection terminals and the display substrate through the plurality of second connection terminals to drive the display substrate to emit light.

In one embodiment, the driving backplane further comprises a substrate layer, and the connecting circuit layer and the driving integrated circuit are disposed on the substrate layer.

In one embodiment, the connecting circuit layer further comprises a connection trace, a first interlayer insulating layer, and a second interlayer insulating layer in the display area, the first interlayer insulating layer is disposed on the substrate layer, the connection trace is disposed on the first interlayer insulating layer, the second interlayer insulating layer is disposed on the connection trace, the second connection terminal is electrically connected to the connection trace and the first connection terminal through a first via hole penetrating the second interlayer insulating layer, the driving integrated circuit in the non-display area is electrically connected to the connection trace, and orthographic projections of the driving integrated circuit and the connection trace projected on the substrate layer do not overlap each other.

In one embodiment, the display substrate comprises: a substrate; a driving circuit layer disposed on a side of the substrate away from the driving backplane; the driving circuit layer is electrically connected to the first connection terminal; and a light-emitting function layer, and the first connection terminal is disposed on a surface of the substrate facing the driving backplane and is electrically connected to the light-emitting function layer.

In one embodiment, the connecting circuit layer further comprises a driving function layer in the display area, the second connection terminal is electrically connected to the driving function layer through a first via hole of the connecting circuit layer, the driving integrated circuit is disposed in the non-display area and electrically contacts the driving function layer, and orthographic projections of the driving integrated circuit and the driving function layer projected on the substrate layer do not overlap each other.

In one embodiment, the connecting circuit layer further comprises a first interlayer insulating layer and a second interlayer insulating layer on the substrate layer. The driving function layer comprises: a second buffer layer disposed on the first interlayer insulating layer; a second semiconductor layer disposed on the second buffer layer; a sixth interlayer insulating layer disposed on the second buffer layer and covering the second semiconductor layer; a third gate disposed on the sixth interlayer insulating layer and being opposite the second semiconductor layer; a seventh interlayer insulating layer disposed on the sixth interlayer insulating layer and covering the third gate, and the second interlayer insulating layer is disposed on the seventh interlayer insulating layer; a fourth gate disposed on the seventh interlayer insulating layer, and the second interlayer insulating layer covers the fourth gate, and the first via hole is electrically connected to the second semiconductor layer; and a third connection terminal and a fourth connection terminal disposed on the second interlayer insulating layer, and the third connection terminal is electrically connected to the fourth connection terminal, the third connection terminal is electrically connected to the second semiconductor layer through a fifth via hole of the connecting circuit layer, and the driving integrated circuit electrically contacts the fourth connection terminal.

In one embodiment, the connecting circuit layer further comprises a driving function layer in the display area, the second connection terminal is electrically connected to the driving function layer through the first via hole, the driving integrated circuit is disposed on the substrate layer in the display area, and the connecting circuit layer is disposed on the drive integrated circuit, the connecting circuit layer is further provided with a sixth via hole, and the driving integrated circuit is electrically connected to the driving function layer through the sixth via hole.

In one embodiment, the connecting circuit layer further includes a first interlayer insulating layer and a second interlayer insulating layer on the substrate layer. The driving function layer comprises: a second buffer layer disposed on the first interlayer insulating layer; a second semiconductor layer disposed on the second buffer layer; a sixth interlayer insulating layer disposed on the second buffer layer and covering the second semiconductor layer; a third gate disposed on the sixth interlayer insulating layer and being opposite the second semiconductor layer; a seventh interlayer insulating layer disposed on the sixth interlayer insulating layer and covering the third gate, and the second interlayer insulating layer is disposed on the seventh interlayer insulating layer; a fourth gate disposed on the seventh interlayer insulating layer, and the second interlayer insulating layer covers the fourth gate, and the first via hole is electrically connected to the second semiconductor layer; and a third connection terminal disposed on the second interlayer insulating layer, and the third connection terminal is electrically connected to the second semiconductor layer through a fifth via hole of the connecting circuit layer and is electrically connected to the driving integrated circuit through the sixth via hole.

In one embodiment, the connecting circuit layer further comprises a sealing layer, and the sealing layer is disposed between the display component and the driving backplane and covers the first connection terminal and the second connection terminal.

In one embodiment, the connecting circuit layer further comprises a sealing layer, and the sealing layer is disposed between the display component and the driving backplane and covers the first connection terminal and the second connection terminal.

### Advantageous Effects of Invention

### Advantageous Effects

A spliced display panel of the display device is provided. A plurality of display components with light-emitting functions are bound to a driving backplane with a driving function. A first connection terminal is disposed on the display component, and a signal line and a second connection terminal are disposed on the driving backplane. The second connection terminal is electrically connected through the signal line, and is electrically connected to the first connection terminal, and then the signal line is electrically connected through a driving integrated circuit, so as to transmit a signal to the display component to drive the display component to emit light. There are few splicing processes, and multiple small-sized display components can be spliced together easily. Furthermore, multiple small-size display components can be spliced into various shapes according to actual needs to realize large-size seamless spliced display and multi-modal spliced display. In addition, no driving function layer is disposed, or the driving function layer and/or the driving integrated circuit is disposed in the connecting circuit layer of the driving backplane to reduce sizes of the frames, and even to realize frameless splicing.

### BRIEF DESCRIPTION OF DRAWINGS

In order to explain the technical solutions in the embodiments of the present application more clearly, the following will briefly introduce the accompanying drawings needed in the description of the embodiments. Obviously, the accompanying drawings in the following description are merely some embodiments of the present application. For those skilled in the art, other drawings can be obtained from these drawings without creative work.

### DESCRIPTION OF DRAWINGS

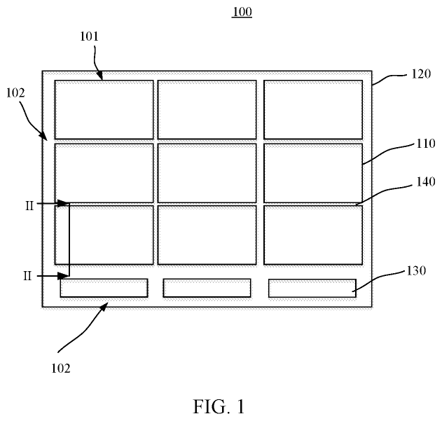

FIG. 1 is a top view of a spliced display panel according to first embodiment of the present application.

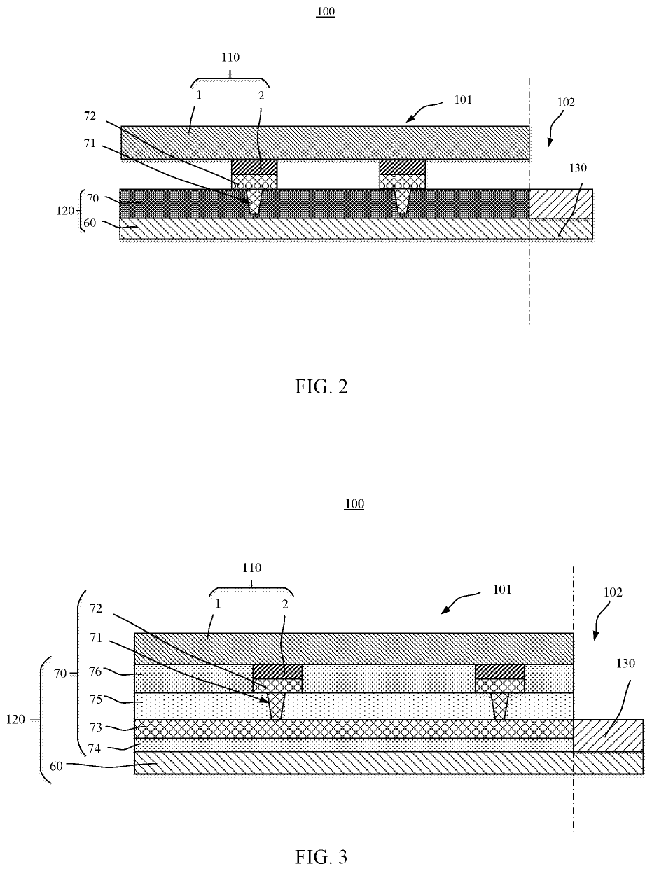

FIG. 2 is a schematic cross-sectional view taken along II-II in FIG. 1.

FIG. 3 is a simple cross-sectional schematic diagram of the spliced display panel with a film structure with a driving backplane shown in FIG. 2.

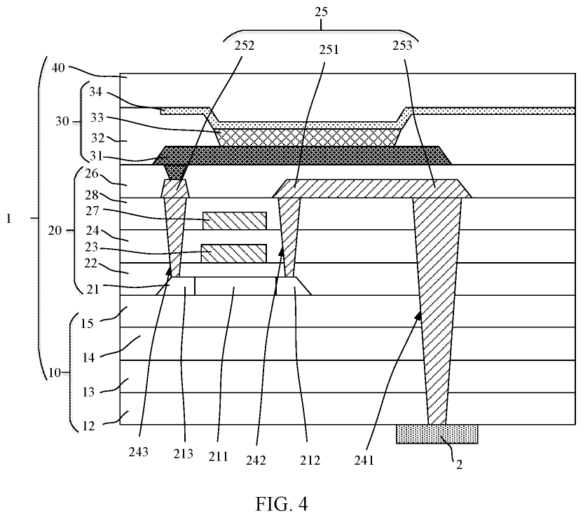

FIG. 4 is a detailed schematic view of the film layer of the display component shown in FIG. 3.

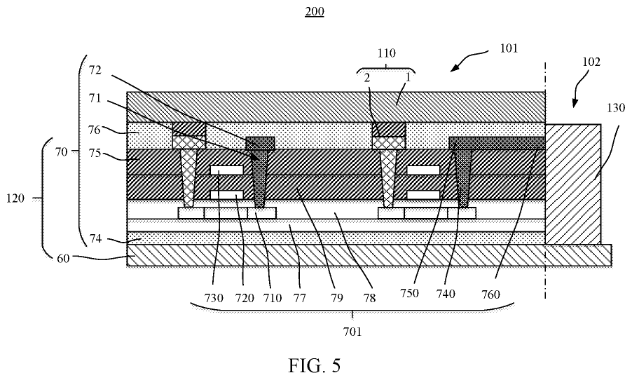

FIG. 5 is a simple cross-section of a spliced display panel with a film structure of a driving backplane according to second embodiment of the present application.

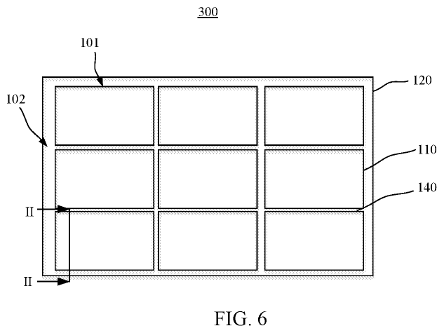

FIG. 6 is a top view of the spliced display panel according to third embodiment of the present application.

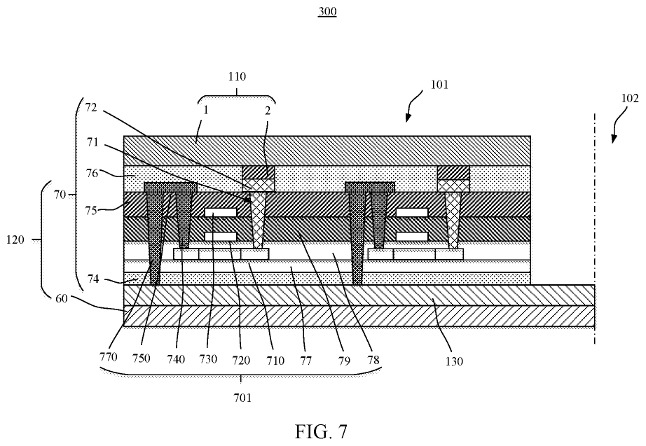

FIG. 7 is a simple cross-sectional view of the spliced display panel shown in FIG. 6.

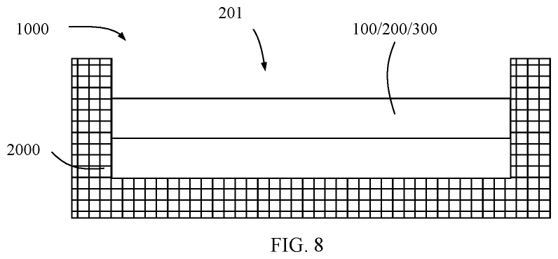

FIG. 8 is a cross-sectional view of a display device according to the present application.

### EXAMPLES OF INVENTION

### Detailed Description of Preferred Embodiments

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application.

In the description of this application, it should be understood that the orientation or positional relationship indicated by the terms “upper”, “lower”, etc. is based on the orientation or positional relationship shown in the drawings, and is only for the convenience of describing the application and simplifying the description. It does not indicate or imply that the pointed device or element must have a specific orientation, be constructed and operated in a specific orientation, and therefore cannot be understood as a limitation of the present application. In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include one or more of the features. In the description of the present application, “plurality” means two or more than two, unless specifically defined otherwise.

This application may repeat reference numerals and/or reference letters in different implementations, and this repetition is for the purpose of simplification and clarity, and does not indicate the relationship between the various embodiments and/or settings discussed.

The present application solves the technical problems of large frame size and complicated process in the spliced display panel of display device in the prior art. In the present application, a plurality of display components with light-emitting functions are bound to a driving backplane with a driving function. A first connection terminal is disposed on the display component, and a signal line and a second connection terminal are disposed on the driving backplane. The second connection terminal is electrically connected through the signal line, and is electrically connected to the first connection terminal, and then the signal line is electrically connected through a driving integrated circuit, so as to transmit a signal to the display component to drive the display component to emit light. There are few splicing processes, and multiple small-sized display components can be spliced together easily. Furthermore, multiple small-size display components can be spliced into various shapes according to actual needs to realize large-size seamless spliced display and multi-modal spliced display. In addition, no driving function layer is disposed, or the driving function layer and/or the driving integrated circuit is disposed in the connecting circuit layer of the driving backplane to reduce sizes of the frames, and even to realize frameless splicing.

Referring to FIG. 1 and FIG. 2, a spliced display panel 100 is provided in first embodiment of the present application. The splicing display panel 100 comprises a display area 101 and a non-display area 102 located outside the display area 101. The spliced display panel 100 further comprises a plurality of display components 110, a driving backplane 120 and a driving integrated circuit 130. A plurality of the display components 110 are disposed in the display area 101, and each of the display components 110 comprises a plurality of first connection terminals 2 and a display substrate 1 electrically connected to the first connection terminals 2. The first connection terminal 2 is disposed on a surface of the display substrate 1 facing the driving backplane 120. A plurality of the display components 110 are arranged in an array on the driving backplane 120. The driving backplane 120 comprises a connecting circuit layer 70 in the display area 101, and the connecting circuit layer 70 comprises a plurality of second connection terminals 72. The first connection terminal 2 is electrically connected to the second connection terminal 72. The driving integrated circuit 130 is electrically connected to the second connection terminal 72. The driving integrated circuit 130 sequentially transmits signals to the first connection terminal 2 and the display substrate 1 through the second connection terminal 72 to drive the display substrate 1 to emit light.

Referring to FIG. 1, in this embodiment, there is an assembly gap 140 between two adjacent display components 110. A plurality of the driving integrated circuits 130 are disposed in the non-display area 102 instead of the assembly gap 140, so that the assembly gap 140 can be reduced, and even seamless splicing can be realized. In this embodiment, a plurality of display components 110 in the same column correspond to one driving integrated circuit 130. That is, one driving integrated circuit 130 can simultaneously control the plurality of display components 110 in the same column to emit light with the same color and brightness.

Certainly, in other embodiments, one driving integrated circuit 130 can simultaneously control all or part of the display components 110 to emit light with the same color and brightness. Specifically, it can be set according to actual conditions.

Referring to FIG. 3, in this embodiment, the connecting circuit layer 70 further comprises a connection trace 73, a first interlayer insulating layer 74, a second interlayer insulating layer 75, and a sealing layer 76. The connection trace 73 is disposed on the first interlayer insulating layer 74. The second interlayer insulating layer 75 is disposed on the connection trace 73. A plurality of first via holes 71 are formed in the second interlayer insulating layer 75. The second connection terminal 72 is disposed on the second interlayer insulating layer 75 and is electrically connected to the connection trace 73 through the first via hole 71. The sealing glue layer 76 is disposed between the second interlayer insulating layer 75 and the display substrate 1 and wraps the second connection terminal 72 and the first connection terminal 2. The connection trace 73 is electrically connected to the second connection terminal 72.

The sealing layer 76 is used to bond the display component 110 and the driving backplane 120 and fix the first connection terminal 2 and the second connection terminal 72. In this embodiment, the sealing layer 76 is an anisotropic conductive film (ACF).

Specifically, the driving integrated circuit 130 in the non-display area 102 is electrically connected to the connection trace 73, and orthographic projections of the driving integrated circuit 130 and the connection trace 73 projected on the substrate layer 60 do not overlap each other. The driving integrated circuit 130 sequentially transmits signals to the second connection terminal 72, the first connection terminal 2, and the display substrate 1 through the connection trace 73 to drive the display substrate 1 to emit light.

Referring to FIG. 2 and FIG. 3, the driving backplane 120 further comprises a substrate layer 60. The connecting circuit layer 70 and the driving integrated circuit 130 are disposed on the substrate layer 60. Specifically, the driving integrated circuit 130 is disposed in the non-display area 102 and is located outside the connecting circuit layer 70.

The material of the substrate layer 60 is selected from at least one of glass, polyimide (PI), polyethylene terephthalate (PET), non-woven fabrics, and laminated film layers.

Referring to FIG. 4, the display substrate 1 comprises a substrate 10, a driving circuit layer 20 disposed on a side of the substrate 10 away from the driving backplane 120, and a light-emitting function layer 30. The first connection terminal 2 is disposed on a surface of the substrate 10 facing the driving backplane 120 and is electrically connected to the light-emitting function layer 30. The driving circuit layer 20 is used to provide a driving voltage to the light-emitting function layer 30 to make the light-emitting function layer 30 emit light. In order to protect the reliability of the light-emitting function layer 30 and prevent water and oxygen intrusion from failing the light-emitting function layer 30, the display assembly 110 further comprises a packaging layer 40.

The substrate 10 comprises a first barrier layer 12 and a first substrate 13 laminated on the first connection terminal 2. The first substrate 13 is disposed between the driving circuit layer 20 and the first barrier layer 12. In this embodiment, the first connection terminal 2 is disposed on a surface of the first barrier layer 12 away from the first substrate 13. In other embodiments, the first barrier layer 12 may also cover the first connection terminal 2, and the lower surface of the first connection terminal 2 is exposed. That is, the first connection terminal 2 is embedded in the first barrier layer 12 and the lower surface of the first connection terminal 2 is exposed. The lower surface of the first connection terminal 2 refers to the surface of the first connection terminal 2 away from the first barrier layer 12, and the lower surface is exposed for electrical connection with the driving backplane 120. The first connection terminal 2 can be made of a metal or alloy or metal laminate structure with strong oxidation resistance and low resistivity, metal oxide, conductive oxide, such as MO, AL, etc., to ensure that the stability of the connection terminal 2 and the reliability of the connection with the driving backplane 120.

Optionally, in this embodiment, the driving circuit layer 20 comprises a transistor with a double gate structure. Specifically, the driving circuit layer 20 comprises a first semiconductor layer 21, a third interlayer insulating layer 22, a first gate 23, a fourth interlayer insulating layer 24, a second gate 27, a fifth interlayer insulating layer 28, and a source and drain layer 25. The first semiconductor layer 21 is disposed on the substrate 10. More specifically, the first semiconductor layer 21 is disposed on the first buffer layer 15. The first semiconductor layer 21 comprises a channel region 211 and a source region 212 and a drain region 213 disposed on opposite sides of the channel region 211. The third interlayer insulating layer 22 covers the first semiconductor layer 21 and the substrate 10. Of course, in other embodiments, the driving circuit layer 20 may also comprises a transistor with a single gate structure.

The first gate 23 is disposed on the third interlayer insulating layer 22, and the first gate 23 is disposed corresponding to the channel region 211 of the first semiconductor layer 21. The fourth interlayer insulating layer 24 covers the first gate 23 and the third interlayer insulating layer 22. The second gate 27 is disposed on the fourth interlayer insulating layer 24 and corresponds to the first gate 23. A capacitor is formed between the second gate 27 and the first gate 23. The fifth interlayer insulating layer 28 covers the second gate 27 and the fourth interlayer insulating layer 24. The source drain layer 25 is disposed on the fifth interlayer insulating layer 28. The source and drain layer 25 is patterned to form a source 251, a drain 252, a data line 253. The source 251 and the drain 252 are electrically connected to the corresponding source region 212 and the drain region 213 of the first semiconductor layer 21. The data line 253 is electrically connected to the corresponding first connection terminal 2.

Specifically, the driving circuit layer 20 further comprises a second via hole 241. The second via hole 241 penetrates the fifth interlayer insulating layer 28, the fourth interlayer insulating layer 24, the third interlayer insulating layer 22, the first buffer layer 15, the second barrier layer 14, the first substrate 13, and the first barrier layer 12, so as to expose a part of upper surface of the first connection terminal 2. The upper surface of the first connecting terminal 2 refers to a surface opposite to the lower surface of the first connecting terminal 2 in parallel. The data line 253 is electrically connected to the first connection terminal 2 through the second via hole 241, and the data line 253 is also electrically connected to the source 251 or the drain 252. The electrical connection between the data line 253 and the source 251 is taken as an example for description.

Furthermore, the driving circuit layer 20 further comprises a third via hole 242 and a fourth via hole 243. The third via hole 242 and the fourth via hole 243 both penetrate the fifth interlayer insulating layer 28, the fourth interlayer insulating layer 24, and a part of the third interlayer insulating layer 22 to expose a part of the first semiconductor layer 21, respectively. The source 251 is electrically connected to the source region of the first semiconductor layer 21 through the third via hole 242, and the drain 252 is electrically connected to the source region of the first semiconductor layer 21 through the fourth via hole 243.

Moreover, in order to provide a flat surface for the driving circuit layer 20, the driving circuit layer 20 further includes a planarization layer 26 covering the source drain layer 25 and the fifth interlayer insulating layer 28.

Of course, the structure of the driving circuit layer 20 in the present application is not limited to that illustrated in this embodiment, and the driving circuit layer 20 in the present application may also include more or fewer film layers. Moreover, the positional relationship of each film layer is not limited to that shown in this embodiment.

Specifically, the light-emitting function layer 30 comprises a pixel electrode 31, a pixel definition layer 32, a light-emitting unit 33, and a cathode 34. The pixel electrode 31 is disposed on the planarization layer 26 and electrically connected to the source 251 or the drain 252 through the via hole of the planarization layer 26. Of course, since this embodiment takes the electrical connection of the data line 253 and the source electrode 251 as an example, this embodiment takes the electrical connection of the pixel electrode 31 and the drain electrode 252 as an example, correspondingly. The pixel definition layer 32 is disposed on the pixel electrode 31 and the planarization layer 26, and the pixel definition layer 32 is patterned to form a pixel opening, and the pixel opening exposes a part of the pixel electrode 31 to define a setting area of the light-emitting unit 33.

The light-emitting unit 33 is formed of a light-emitting material vapor-deposited or printed in the pixel opening of the pixel defining layer 32, and light-emitting materials with different colors form different colors of light-emitting unit 33. For example, the light-emitting unit 33 may comprise a red light-emitting unit formed of a red light-emitting material, a green light-emitting unit formed of a green light-emitting material, and a blue light-emitting unit formed of a blue light-emitting material. The red light-emitting unit emits red light, the green light-emitting unit emits green light, and the blue light emitting unit emits blue light.

The cathode 34 covers the light-emitting unit 33 and the pixel definition layer 32. The light-emitting unit 33 emits light under the combined action of the pixel electrode 31 and the cathode 34, and the light-emitting unit 33 with different colors emits different colors of light, thereby realizing the pixel display of the display component 110.

Optionally, the pixel electrode 31 may be a transparent electrode or a reflective electrode. If the pixel electrode 31 is a transparent electrode, the pixel electrode 31 may be made of, for example, indium tin oxide (ITO), indium zinc oxide (IZO), ZnO or In₂O₃. If the pixel electrode 31 is a reflective electrode, the pixel electrode 31 may comprise, for example, a reflective layer formed of Ag, Mg, Al, Pt, Pd, Au, Ni, Nd, Ir, Cr, or a combination thereof and a reflective layer formed of ITO, IZO, ZnO, or In₂O₃ layer. However, the pixel electrode 31 is not limited thereto, and the pixel electrode 31 may be formed of various materials, and may also be formed in a single-layer or multi-layer structure.

It should be noted that whether the pixel electrode 31 is a transparent electrode or a reflective electrode depends on the light emitting direction of the spliced display panel 100. When the spliced display panel 100 adopts top-emission light, the pixel electrode 31 may be a transparent electrode or a reflective electrode. Of course, the utilization of light emitted by the light-emitting unit 33 can be improved when the reflective electrode is adopted. When the spliced display panel 100 adopts bottom-emission light, the pixel electrode 31 adopts a transparent electrode to increase the light transmittance. In this embodiment, the spliced display panel 100 adopts top-emitting light as an example. Therefore, in order to increase the light transmittance, the cathode 34 needs to be formed of a transparent conductive material. For example, the cathode 34 may be formed of a transparent conductive oxide (TCO), such as ITO, IZO, ZnO, or In₂O₃.

Optionally, the light-emitting functional layer 30 may further comprise a hole injection layer (HIL, not shown) disposed between the light-emitting unit 33 and the pixel electrode 31, a hole transport layer (HTL, not shown), an electron injection layer (EIL, not shown) disposed between the light-emitting unit 33 and the cathode 34, and an electron transport layer (ETL, not shown). The hole injection layer receives holes transmitted by the pixel electrode 31. The holes are transmitted to the light emitting unit 33 through the hole transport layer. The electron injection layer receives electrons transmitted from the cathode 34, and the electrons are transmitted to the light emitting unit 33 through the electron transport layer. Holes and electrons are combined at the position of the light-emitting unit 33 to generate excitons, and the excitons transition from the excited state to the ground state to release energy and emit light.

The packaging layer 40 covers the light-emitting functional layer 30 and is used to protect the light-emitting unit 33 of the light-emitting functional layer 30 to prevent water and oxygen from invading and causing the light-emitting unit 33 to fail. Optionally, the packaging layer 40 may be encapsulated by a thin film. For example, the packaging layer 40 may be a laminated structure formed by successively stacking three films of a first inorganic packaging layer, an organic packaging layer, and a second inorganic packaging layer, or a multi-layer laminated structure.

In this embodiment, the display component 110 further comprises a gate driving circuit (not shown). The gate driving circuit is electrically connected to the driving circuit layer 20 for providing scanning signals.

In this embodiment, the spliced display panel 100 uses the driver integrated circuit 130 and the connection trace 73 to sequentially transmit the signals in the driver integrated circuit 130 to the second connection terminal 72, the first connection terminal 2, a driving circuit layer 20, and the light-emitting function layer 30, in combination with the gate driving circuit in the display component 110, to drive the display component 110 to emit light. Since a plurality of display components 110 share one driving integrated circuit 130 in this embodiment, compared with a corresponding driving integrated circuit for each display component in the prior art, the frame area occupied by the driving integrated circuit can be effectively reduced. In addition, the connection trace 73 connecting the display component 110 and the driving integrated circuit 130 is disposed in the connecting circuit layer 70 of the driving backplane 120, which does not need to occupy the area of the frame. Compared with the fan-out wiring connecting the display component and the driving integrated circuit in the prior art, which needs to occupy a certain frame area, the area of the peripheral circuit can be effectively reduced, so that small frame spliced display can be realized.

Referring to FIG. 5, a spliced display panel 200 is provided in a second embodiment of the present application. The structure of the spliced display panel 200 is similar to the structure of the spliced display panel 100. The difference is that the connecting circuit layer 70 of the spliced display panel 200 further comprises a driving function layer 701 formed on the substrate layer 60 in the display area 101, and the second connection terminal 72 is electrically connected to the driving function layer 701 through the first via hole 71, and the driving integrated circuit 130 is electrically connected to the driving function layer 701. The orthographic projections of the driving integrated circuit 130 and the driving function layer 701 projected on the substrate layer 60 do not overlap each other.

In this embodiment, the driving function layer 701 comprises a plurality of driving transistors with a double gate structure. Specifically, the driving function layer 701 comprises a second buffer layer 77 disposed on the first interlayer insulating layer 74, a second semiconductor layer 710 disposed on the second buffer layer 77, a sixth interlayer insulating layer 78 disposed on the second buffer layer 77 and covering the second semiconductor layer 710, a third gate 720 disposed on the sixth interlayer insulating layer 78 and being opposite the second semiconductor layer 710, a seventh interlayer insulating layer 79 disposed on the sixth interlayer insulating layer 78 and covering the third gate 720, and a fourth gate 730 disposed on the seventh interlayer insulating layer 79. The second interlayer insulating layer 75 is disposed on the seventh interlayer insulating layer 79 and covers the fourth gate 730. The first via hole 71 penetrates the second interlayer insulating layer 75, the seventh interlayer insulating layer 79, and a part of the sixth interlayer insulating layer 78 and is electrically connected to the second semiconductor layer 710.

The driving function layer 701 further comprises a plurality of fifth via holes 740 and a plurality of third connection terminals 750 and fourth connection terminals 760 disposed at one end of the fifth via hole 740 away from the second semiconductor layer 710 and electrically connected to the fifth via 740. The fourth connection terminal 760 is an extension of the third connection terminal 750 or they remain electrically connecting to each other. The third connection terminal 750 and the second connection terminal 72 constitute the source and the drain of the driving function layer 701. Each of the fifth via holes 740 penetrates the second interlayer insulating layer 75, the seventh interlayer insulating layer 79, and a part of the sixth interlayer insulating layer 78 and is electrically connected to the second semiconductor layer 710. The driving integrated circuit 130 is electrically connected to the third connection terminal 750 through the fourth connection terminal 760.

In other embodiments, the driving function layer 701 may further comprise a driving transistor with a single gate structure.

In this embodiment, the driving integrated circuit 130 is disposed in the non-display area 102. The driving signal from the driving integrated circuit 130 are transmitted to the display substrate 1 through the fourth connection terminal 760, the third connection terminal 750, the fifth via hole 740, the second semiconductor layer 710, and the first via hole 71, the second connection terminal 72, and the first connection terminal 2, so as to drive the display substrate 1 to emit light.

In other embodiments, the structure of the driving function layer 701 is not limited to the structure described above.

The driving function layer 701 is disposed in the display area 101 and can further reduce the area of the peripheral circuit, and realize narrow frame of spliced display.

Referring to FIG. 6 and FIG. 7, a spliced display panel 300 in a third embodiment of the present application, the structure of the spliced display panel 300 is similar to the structure of the spliced display panel 200. The difference is that the driving function layer 701 does not comprise the fourth connection terminal 760. The driving integrated circuit 130 is disposed on the substrate layer 60 in the display area 101, and the connecting circuit layer 70 is disposed on the driver integrated circuit 130. Specifically, the first interlayer insulating layer 74 is disposed on the driving integrated circuit 130. The driving function layer 701 is electrically connected to the driving integrated circuit 130, and the second connection terminal 72 is electrically connected to the driving function layer 701. The driving function layer 701 serves as a gate driving circuit (GOA circuit) of the spliced display panel 300.

Specifically, the driving function layer 701 further comprises a plurality of sixth via holes 770. Each of the sixth via holes 770 is electrically connected to one of the third connection terminals 750 and penetrates the second interlayer insulating layer 75, the seventh interlayer insulating layer 79, the sixth interlayer insulating layer 78, the second buffer layer 77, and the first interlayer insulating layer 74, and then it is electrically connected to the driving integrated circuit 130.

In this embodiment, the driving function layer 701 is disposed in the display area 101 and simultaneously the driving integrated circuit 130 is disposed in the form of a film on the substrate layer 60 in the display area 101, so the area of peripheral circuits can be further reduced. Therefore, a narrow frame of spliced display us realized.

Referring to FIG. 8, a display device 1000 is also provided. The display device 1000 comprises a housing 2000 and one of the spliced display panel 100, the spliced display panel 200, and the spliced display panel 300 in the above embodiments, and the housing 2000 defines a containing cavity 201, the spliced display panel 100, the spliced display panel 200, or the spliced display panel 300 is disposed in the containing cavity 201.

A spliced display panel of the display device is provided. A plurality of display components with light-emitting functions are bound to a driving backplane with a driving function. A first connection terminal is disposed on the display component, and a signal line and a second connection terminal are disposed on the driving backplane. The second connection terminal is electrically connected to the first connection terminal through the signal line, and then is electrically connected to the signal trace through a driving integrated circuit, so as to transmit a signal to the display component to drive the display component to emit light. Since there are fewer splicing processes, and multiple small-sized display components can be spliced together easily. Furthermore, multiple small-size display components can be spliced into various shapes according to actual needs to realize large-size seamless spliced display and multi-modal spliced display.

In addition, a driving function layer is not disposed in the driving backplane, but a driving integrated circuit and connection trace are disposed in the driving backplane. The signals in the driving integrated circuit are sequentially transmitted to the second connection terminal, the first connection terminal, the driving circuit layer, and the light-emitting function layer through the driving integrated circuit and the connection trace, in combination with the gate driving circuit in the display component, to drive the display component to emit light. Since a plurality of display components share one driving integrated circuit, compared with the prior art that each of display components is provided with a corresponding driving integrated circuit, the frame area occupied by the driving integrated circuit can be effectively reduced. In addition, the connection traces connecting the display components and the driving integrated circuit are disposed in the connecting circuit layer of the driving backplane, which does not need to occupy the area of the frame area. Compared with the fan-out wiring connecting the display component and the driving integrated circuit in the prior art, which needs to occupy a certain frame area, the area of the peripheral circuit can be effectively reduced in the embodiments, so that small frame spliced display can be realized.

In addition, the driving function layer disposed in the display area can further reduce the area of the peripheral circuit, and realize narrow frame of spliced display.

Furthermore, the driving function layer is disposed in the display area, and simultaneously the driving integrated circuit is disposed in the form of a film on the substrate in the display area, so the area of the peripheral circuit can be further reduced, and the area of the peripheral circuit can be further reduced to realize a narrow frame of spliced display.

In the above, the present application has been described in the above preferred embodiments, but the preferred embodiments are not intended to limit the scope of the application, and a person skilled in the art may make various modifications without departing from the spirit and scope of the application. The scope of the present application is determined by claims.

What is claimed is:

1. A spliced display panel, comprising:
a display area; and
a non-display area on a side of the display area, wherein the spliced display panel further comprises:
a plurality of display components in the display area, wherein each of the display components comprises a plurality of first connection terminals and a display substrate electrically connected to the first connection terminals;
a driving backplane comprising a connecting circuit layer in the display area, wherein the connecting circuit layer comprises a plurality of second connection terminals bound to the plurality of first connection terminals, and a plurality of the display components are arranged in an array on the driving backplane; and
a driving integrated circuit electrically connected to the plurality of second connection terminals;
wherein the driving integrated circuit sequentially transmits signals to the plurality of first connection terminals and the display substrate through the plurality of second connection terminals to drive the display substrate to emit light.

2. The spliced display panel according to claim 1, wherein the driving backplane further comprises a substrate layer, and the connecting circuit layer and the driving integrated circuit are disposed on the substrate layer.

3. The spliced display panel according to claim 2, wherein the connecting circuit layer further comprises a connection trace, a first interlayer insulating layer, and a second interlayer insulating layer in the display area, the first interlayer insulating layer is disposed on the substrate layer, the connection trace is disposed on the first interlayer insulating layer, the second interlayer insulating layer is disposed on the connection trace, the second connection terminal is electrically connected to the connection trace and the first connection terminal through a first via hole penetrating the second interlayer insulating layer, the driving integrated circuit in the non-display area is electrically connected to the connection trace, and orthographic projections of the driving integrated circuit and the connection trace projected on the substrate layer do not overlap each other.

4. The spliced display panel according to claim 3, wherein the display substrate comprises:
a substrate;
a driving circuit layer disposed on a side of the substrate away from the driving backplane; the driving circuit layer is electrically connected to the first connection terminal; and
a light-emitting function layer, wherein the first connection terminal is disposed on a surface of the substrate facing the driving backplane and is electrically connected to the light-emitting function layer.

5. The spliced display panel according to claim 2, wherein the connecting circuit layer further comprises a driving function layer in the display area, the second connection terminal is electrically connected to the driving function layer through a first via hole of the connecting circuit layer, the driving integrated circuit is disposed in the non-display area and electrically contacts the driving function layer, and orthographic projections of the driving integrated circuit and the driving function layer projected on the substrate layer do not overlap each other.

6. The spliced display panel according to claim 5, wherein the connecting circuit layer further comprises a first interlayer insulating layer and a second interlayer insulating layer on the substrate layer;
wherein the driving function layer comprises:
a second buffer layer disposed on the first interlayer insulating layer;
a second semiconductor layer disposed on the second buffer layer;
a sixth interlayer insulating layer disposed on the second buffer layer and covering the second semiconductor layer;
a third gate disposed on the sixth interlayer insulating layer and being opposite the second semiconductor layer;
a seventh interlayer insulating layer disposed on the sixth interlayer insulating layer and covering the third gate, wherein the second interlayer insulating layer is disposed on the seventh interlayer insulating layer;
a fourth gate disposed on the seventh interlayer insulating layer, wherein the second interlayer insulating layer covers the fourth gate, and the first via hole is electrically connected to the second semiconductor layer; and
a third connection terminal and a fourth connection terminal disposed on the second interlayer insulating layer, wherein the third connection terminal is electrically connected to the fourth connection terminal, the third connection terminal is electrically connected to the second semiconductor layer through a fifth via hole of the connecting circuit layer, and the driving integrated circuit electrically contacts the fourth connection terminal.

7. The spliced display panel according to claim 2, wherein the connecting circuit layer further comprises a driving function layer in the display area, the second connection terminal is electrically connected to the driving function layer through the first via hole, the driving integrated circuit is disposed on the substrate layer in the display area, and the connecting circuit layer is disposed on the drive integrated circuit, the connecting circuit layer is further provided with a sixth via hole, and the driving integrated circuit is electrically connected to the driving function layer through the sixth via hole.

8. The spliced display panel according to claim 7, wherein the connecting circuit layer further comprises a first interlayer insulating layer and a second interlayer insulating layer on the substrate layer; and
wherein the driving function layer comprises:
a second buffer layer disposed on the first interlayer insulating layer;
a second semiconductor layer disposed on the second buffer layer;
a sixth interlayer insulating layer disposed on the second buffer layer and covering the second semiconductor layer;
a third gate disposed on the sixth interlayer insulating layer and being opposite the second semiconductor layer;
a seventh interlayer insulating layer disposed on the sixth interlayer insulating layer and covering the third gate, wherein the second interlayer insulating layer is disposed on the seventh interlayer insulating layer;
a fourth gate disposed on the seventh interlayer insulating layer, wherein the second interlayer insulating layer covers the fourth gate, and the first via hole is electrically connected to the second semiconductor layer; and
a third connection terminal disposed on the second interlayer insulating layer, wherein the third connection terminal is electrically connected to the second semiconductor layer through a fifth via hole of the connecting circuit layer and is electrically connected to the driving integrated circuit through the sixth via hole.

9. The spliced display panel according to claim 1, wherein the connecting circuit layer further comprises a sealing layer, and the sealing layer is disposed between the display component and the driving backplane and covers the first connection terminal and the second connection terminal.

10. The spliced display panel according to claim 2, wherein the connecting circuit layer further comprises a sealing layer, and the sealing layer is disposed between the display component and the driving backplane and covers the first connection terminal and the second connection terminal.

11. A display device, comprising:
a housing defining a containing cavity; and
a spliced display panel, wherein the spliced display panel is disposed in the containing cavity;
wherein the spliced display panel comprises a display area and a non-display area on a side of the display area;
wherein the spliced display panel further comprises:
a plurality of display components in the display area, wherein each of the display components comprises a plurality of first connection terminals and a display substrate electrically connected to the first connection terminals;
a driving backplane comprising a connecting circuit layer in the display area, wherein the connecting circuit layer comprises a plurality of second connection terminals bound to the plurality of first connection terminals, and a plurality of the display components are arranged in an array on the driving backplane; and
a driving integrated circuit electrically connected to the plurality of second connection terminals, wherein the driving integrated circuit sequentially transmits signals to the plurality of first connection terminals and the display substrate through the plurality of second connection terminals to drive the display substrate to emit light.

12. The display device according to claim 11, wherein the driving backplane further comprises a substrate layer, and the connecting circuit layer and the driving integrated circuit are disposed on the substrate layer.

13. The display device according to claim 12, wherein the connecting circuit layer further comprises a connection trace, a first interlayer insulating layer, and a second interlayer insulating layer in the display area, the first interlayer insulating layer is disposed on the substrate layer, the connection trace is disposed on the first interlayer insulating layer, the second interlayer insulating layer is disposed on the connection trace, the second connection terminal is electrically connected to the connection trace and the first connection terminal through a first via hole penetrating the second interlayer insulating layer, the driving integrated circuit in the non-display area is electrically connected to the connection trace, and orthographic projections of the driving integrated circuit and the connection trace projected on the substrate layer do not overlap each other.

14. The display device according to claim 13, wherein the display substrate comprises:
a substrate;
a driving circuit layer disposed on a side of the substrate away from the driving backplane; the driving circuit layer is electrically connected to the first connection terminal; and
a light-emitting function layer, wherein the first connection terminal is disposed on a surface of the substrate facing the driving backplane and is electrically connected to the light-emitting function layer.

15. The display device according to claim 12, wherein the connecting circuit layer further comprises a driving function layer in the display area, the second connection terminal is electrically connected to the driving function layer through a first via hole of the connecting circuit layer, the driving integrated circuit is disposed in the non-display area and electrically contacts the driving function layer, and orthographic projections of the driving integrated circuit and the driving function layer projected on the substrate layer do not overlap each other.

16. The display device according to claim 15, wherein the connecting circuit layer further comprises a first interlayer insulating layer and a second interlayer insulating layer on the substrate layer;
wherein the driving function layer comprises:
a second buffer layer disposed on the first interlayer insulating layer;
a second semiconductor layer disposed on the second buffer layer;
a sixth interlayer insulating layer disposed on the second buffer layer and covering the second semiconductor layer;
a third gate disposed on the sixth interlayer insulating layer and being opposite the second semiconductor layer;
a seventh interlayer insulating layer disposed on the sixth interlayer insulating layer and covering the third gate, wherein the second interlayer insulating layer is disposed on the seventh interlayer insulating layer;
a fourth gate disposed on the seventh interlayer insulating layer, wherein the second interlayer insulating layer covers the fourth gate, and the first via hole is electrically connected to the second semiconductor layer; and
a third connection terminal and a fourth connection terminal disposed on the second interlayer insulating layer, wherein the third connection terminal is electrically connected to the fourth connection terminal, the third connection terminal is electrically connected to the second semiconductor layer through a fifth via hole of the connecting circuit layer, and the driving integrated circuit electrically contacts the fourth connection terminal.

17. The display device according to claim 12, wherein the connecting circuit layer further comprises a driving function layer in the display area, the second connection terminal is electrically connected to the driving function layer through the first via hole, the driving integrated circuit is disposed on the substrate layer in the display area, and the connecting circuit layer is disposed on the drive integrated circuit, the connecting circuit layer is further provided with a sixth via hole, and the driving integrated circuit is electrically connected to the driving function layer through the sixth via hole.

18. The display device according to claim 17, wherein the connecting circuit layer further comprises a first interlayer insulating layer and a second interlayer insulating layer on the substrate layer; and
wherein the driving function layer comprises:
a second buffer layer disposed on the first interlayer insulating layer;
a second semiconductor layer disposed on the second buffer layer;
a sixth interlayer insulating layer disposed on the second buffer layer and covering the second semiconductor layer;
a third gate disposed on the sixth interlayer insulating layer and being opposite the second semiconductor layer;
a seventh interlayer insulating layer disposed on the sixth interlayer insulating layer and covering the third gate, wherein the second interlayer insulating layer is disposed on the seventh interlayer insulating layer;
a fourth gate disposed on the seventh interlayer insulating layer, wherein the second interlayer insulating layer covers the fourth gate, and the first via hole is electrically connected to the second semiconductor layer; and
a third connection terminal disposed on the second interlayer insulating layer, wherein the third connection terminal is electrically connected to the second semiconductor layer through a fifth via hole of the connecting circuit layer and is electrically connected to the driving integrated circuit through the sixth via hole.

19. The display device according to claim 11, wherein the connecting circuit layer further comprises a sealing layer, and the sealing layer is disposed between the display component and the driving backplane and covers the first connection terminal and the second connection terminal.

20. The display device according to claim 12, wherein the connecting circuit layer further comprises a sealing layer, and the sealing layer is disposed between the display component and the driving backplane and covers the first connection terminal and the second connection terminal.
